(19) United States
(12) Patent Application Publication
(10) Pub. No.: US 2025/0028239 A1
(43) Pub. Date: Jan. 23, 2025

(54) BASEPLATE FOR SUPPORTING A RETICLE AND RELATED SYSTEMS AND METHODS

(71) Applicant: ENTEGRIS, INC., Billerica, MA (US)

(72) Inventors: Huaping Wang, Eden Prairie, MN (US); Russ V. Raschke, Chanhassen, MN (US); Brian Wiseman, Glencoe, MN (US)

(21) Appl. No.: 18/733,572

(22) Filed: Jun. 4, 2024

Related U.S. Application Data
(60) Provisional application No. 63/545,534, filed on Oct. 24, 2023.
(60) Provisional application No. 63/528,286, filed on Jul. 21, 2023.

(51) Int. Cl. G03F 1/66; G03F 1/84

(52) U.S. Cl. CPC G03F 1/66; G03F 1/84

(57) ABSTRACT

Described are baseplate devices used to support, transport, and process a reticle, including to support a reticle during a step of detecting particle contamination at a surface of the reticle prior to using the reticle in an extreme ultraviolet (EUV) lithography process.

### FIELD

The present description relates to baseplate devices used to support, transport, and process a reticle, including to support a reticle during a step of detecting particle contamination at a surface of the reticle prior to using the reticle in an extreme ultraviolet (EUV) lithography process.

### BACKGROUND

One of the process steps commonly used in the fabrication of integrated circuits and other microelectronic and semiconductor devices is photolithography. Broadly, photolithography involves selectively exposing a specially prepared surface to a source of radiation using a patterned template to create an etched surface layer. According to specific methods, the patterned template is a reticle, which is a very flat glass plate that contains a pattern to be reproduced on the surface.

Photolithography steps may be used multiple times when preparing microelectronic devices on a semiconductor wafer substrate. Useful photolithographic techniques can use various wavelengths of light, including light in an ultraviolet range, light in a deep ultraviolet range, and light in an extreme ultraviolet range.

In certain example processes a semiconductor wafer surface may be prepared by first depositing silicon nitride onto the surface followed by a coating of a light-sensitive liquid polymer or photoresist. Next, ultraviolet (UV) light, e.g., extreme ultraviolet light (“EUV”) is transmitted through or reflected off a surface of a mask or reticle to project a desired pattern onto the photoresist-covered wafer. The portion of the photoresist that is exposed to the light is chemically modified and remains unaffected when the wafer is subsequently subjected to a chemical media that removes the unexposed photoresist, leaving the modified photoresist on the wafer in the shape of the pattern on the mask. The wafer is then subjected to an etch process that removes the exposed portion of the nitride layer leaving a nitride pattern on the wafer in the exact design of the mask.

When photolithography is performed using EUV light, patterned light is applied to the photoresist by being reflected off of a patterned reticle, as opposed to being transmitted through a patterned mask. To achieve the highest level of reflection of light from a reticle (a.k.a. a “reflective photomask”) onto the photoresist, a surface of a reticle that receives EUV light for reflection must be free as free as possible from defects, contamination, and damage. Particle contamination at a surface of a reticle can be detrimental to the performance of the reticle during EUV photolithography. Particle contamination at a surface of the reticle can have the effect of interfering with the reflected light and can also affect the shape or the positioning of the reticle, either of which will change the direction and quality of the reflected light.

### SUMMARY

To reduce or avoid the presence of particle contamination on a reticle surface during a photolithography step, specialized devices and systems are used to detect particle contamination on the reticle surface before use of the reticle in a photolithography step. These systems are sometimes referred to as “reticle backside inspection” (RBI) devices or modules, and may be included as a separate module in a larger EUV photolithography system. During inspection, the reticle is supported by a flat surface of a baseplate, sometimes referred to as an “EUV baseplate” or “baseplate,” herein. The baseplate is useful to support, carry, and transfer the reticle during different steps of preparing for and performing an EUV photolithography step using the reticle.

A backside inspection system operates to detect particles present on a backside (non-patterned) surface of a reticle by shining light onto the backside surface while the patterned (opposite) surface of the reticle is supported horizontally by a baseplate. See FIG. 1 and related text, herein. The light is directed at the reticle backside surface at a shallow angle. If the light is not interrupted by particle contamination at the surface, the light will reflect off of the surface at the same shallow angle (“angle of reflection”).

But if particles are present at the surface, light that is directed at the surface at the shallow angle is re-directed (deflected, reflected, scattered, etc.) away from the reticle surface in various directions other than the shallow angle of reflection. A reticle backside inspection system detector includes a camera located above the reticle, facing downward toward the reticle backside surface. A portion of light that is caused to be scattered and re-directed away from the reticle surface by particles at the surface is received by the camera. The camera associates the re-directed light with the presence of particle contamination at the surface.

In addition to the light reflecting off of particle contamination, it is also possible for light directed at the reticle surface deflect off of a baseplate used to support the reticle during an inspection step. The light used for inspecting the backside surface may pass through transparent portions of the reticle and reach the baseplate. Edge portions at the perimeter of an EUV reticle are often transparent, and light used to detect particles at the reticle surface may pass through the reticle at the transparent edges and reach the baseplate below. Often, the light may be reflected off of the baseplate in a direction that does not reach the camera. But some structures present on a baseplate have the potential to re-direct (reflect or deflect) the light toward the camera. If light is re-directed from the baseplate to the camera, the camera will associate that light with the presence of particle contamination on the reticle backside surface, i.e., the system will produce a “false positive” reading by the detector of a particle being present at the surface, when no particle is present.

A need exists in these reticle backside inspection systems to reduce or avoid the occurrence of false positive readings that are caused by light being reflected off of an EUV baseplate and toward a camera, which associates the light with particle contamination.

According to the present description, an EUV baseplate and baseplate structures such as a reticle support can be designed to prevent or to reduce an amount of light used in a reticle backside inspection system that is reflected from the baseplate, e.g., by edge structures of the baseplate, and re-directed to a camera of a reticle backside inspection system. The baseplate can include features that reduce the amount of that light that is deflected or reflected from an edge surface of the baseplate in a direction that would cause the deflected light to reach a camera of the system and register a false positive reading. These features include “low-reflecting surfaces” applied to or formed on an edge structure.

One type of low-reflective surface is a surface that is shaped or angled to prevent light that is reflected from the low-reflective surface from being re-directed in a direction toward the camera. Examples of this type of low-reflective surfaces include surfaces of an edge structure that have a low radius of curvature, and surfaces of an edge structure that have a flat, beveled (“chamfered”) surface that directs any light that hits the surface in a direction away from the camera.

A low-reflective surface may additionally or alternately be made of or coated with a material that is designed to have a low reflectivity, e.g., a low spectral reflectance of light of a wavelength emitted by an illuminator. The low-reflective surface may be a surface that is treated by a process such as chemical etching, laser ablation, laser texturing, mechanical abrasion, etc., e.g., to form a roughened surface that exhibits a relatively low reflectivity relative to the surface before the treatment, e.g., that causes the light to scatter over a range of directions away from the surface. The low-reflective surface may also be a coated material that is applied to a surface, with the coated material having a low spectral reflectance of light of a wavelength emitted by an illuminator.

Additionally or alternately, a baseplate can include a feature (e.g., a “mask” or “screen”) that, with the reticle being supported by a baseplate, blocks light that is emitted by an illuminator before the light reaches the reticle, to prevent the light from passing through a transparent portion of the reticle such as at a transparent edge, and reaching the baseplate at an area of an edge structure and potentially be re-directed by the edge structure toward the camera.

In one aspect, the invention relates to a baseplate for supporting a reticle. The baseplate includes: a horizontal upper baseplate surface and one or more edge structures. An example of an edge structure is an edge of an aperture located vertically through the plate, the aperture comprising an aperture edge structure formed between a vertical aperture sidewall and the upper baseplate surface. Another example of an edge structure is an edge structure of a reticle support located within the aperture. A reticle support may include: a reticle support body that engages the aperture sidewall; an upper reticle support surface that is located above the upper baseplate surface and is adapted to support a reticle above the upper baseplate surface; and a reticle support edge structure formed between the reticle support body and the upper reticle support surface. A baseplate that includes these or edge structures may include a low-reflecting surface at the edge structure. For example, an aperture edge structure may include a low-reflecting surface in the form of: a bevel; a radius of curvature of less than 0.3 millimeters; a surface having a spectral reflectance that is at least 10 percent lower than a spectral reflectance of the upper baseplate surface; or a combination of these. A reticle support edge structure may include a low-reflecting surface in the form of: a bevel; a radius of curvature of less than 0.3 millimeters; a surface having a spectral reflectance that is at least 10 percent lower than a spectral reflectance of the upper baseplate surface, or a combination of these.

In another aspect, the invention relates to a reticle backside inspection device that includes: a vacuum chamber with an interior; a baseplate according to the present description and claims, at the interior; an illuminator capable of directing light onto a surface of a reticle supported at the baseplate upper surface; and a camera adapted to detect light re-directed by particles on the reticle surface.

In yet another aspect, the invention relates to a method of using a reticle backside inspection system as described herein in a reticle backside particle inspection system, to detect particles at a backside surface of a reticle. The method includes using a reticle backside inspection system that includes: a vacuum chamber with an interior; a baseplate according to the present description and claims, at the interior; an illuminator capable of directing light onto the baseplate upper surface; a reticle supported on the baseplate; and a camera adapted to detect light re-directed by particles at the baseplate upper surface to detect particles on the reticle backside. The method further includes directing light from the illuminator onto the reticle backside surface, baseplate upper surface, and using the camera to detect light reflected by particles at the baseplate upper surface. The method may further include using the light detected by the camera to determine an amount of particles that are present at the baseplate upper surface.

### SUMMARY OF THE DRAWINGS

FIG. 1 shows a side cut-away view of an example reticle backside inspection system as described.

FIGS. 2A and 2B are side perspective views of example baseplates as described.

FIG. 3 is a side perspective view of an example baseplates as described.

FIGS. 4A, 4B, 4C, and 4D are side cut-away views of example baseplates as described, including edge structures.

FIG. 5 shows a side cut-away view of an example reticle backside inspection system as described.

FIG. 6 depicts a cut-away view of another embodiment of a light screed as described.

FIG. 7 shows a cut-away of additional embodiments as described.

FIG. 8 depicts a cut-away view of another embodiment of light blocked by an aperture edge structure and by a reticle support edge structure.

All figures are schematic and are not to scale.

### DETAILED DESCRIPTION

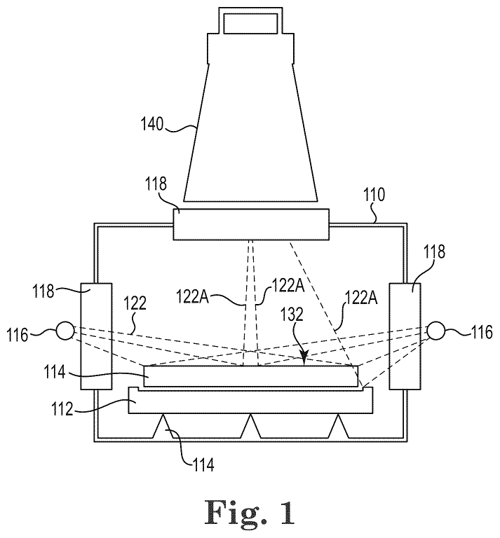

FIG. 1 shows an example of a reticle backside inspection system that can be used to detect unwanted particle contamination in the form of very small particles (e.g., particles having dimensions on a micron scale), at low levels, at a backside surface of a reticle. The particles on the reticle surface may be particles of dust, surface debris carried by a different surface and transferred through the air to the reticle surface, surface debris created by being sloughed from different surface and transferred through the air to the reticle surface.

The particles are minutely small (e.g., having dimensions on a scale of microns) and may be present in very low amounts on the reticle baskside surface. Systems and methods for detecting these particles, even with their very small sizes (based on volume, mass, or both) and if present at very low amounts on a reticle backside surface, are important for semiconductor manufacturing because these small particles present at low levels on a reticle backside surface are capable of having a material effect on the performance of a reticle during a photolithography step.

As illustrated at FIG. 1, system 100 includes a vacuum housing 110 which defines a vacuum chamber 108 at the interior. A reticle baseplate (a.k.a. “EIP baseplate” or EUV inner pod baseplate”) 112 is supported by kinematic mount 114 within vacuum chamber 108. Reticle 130 is supported at a lower (patterned) surface 134 by baseplate 112, and an upper surface (the reticle “backside”) 132 is facing upward toward vacuum chamber 108 and camera 140. Illuminators 116 produce light 122 at a wavelength that passes through windows 118. Light 122 is directed toward surface 132 to inspect for particles that may be present at surface 132.

Light 122 is directed toward surface 132 at a shallow angle of incidence that will cause light 122 from illuminators 116 to be reflected from surface 132 at the same shallow angle (angle of reflection) and will not be reflected in a direction that would allow the reflected light to be detected by camera 140. In the illustrated example, system 100 includes camera 140 located above reticle 130, and at an angle that is perpendicular to the horizontal surface of reticle 130. Light reflected directly off of surface 132 at a shallow angle of reflection will not be received by camera 140. If no particles are present at surface 132 to re-direct light 122 from a shallow angle of reflection at surface 132, not more than a very low and predictable amount of light will become directed toward camera 140 and detected by camera 140.

If, however, particle contamination is present at surface 132, light 122 from illuminators 116 will be deflected or reflected by the particles and scattered over a range of directions within vacuum chamber 108, including in a direction toward camera 140 as deflected light 122A. Deflected light 122 that is received by camera 140 will be associated with the presence of particle contamination present at surface 132. By this arrangement, camera 140 receives and detects light 122A that is deflected by particle contaminants present at surface 132 and registers the deflected light as a being caused by particle contamination at surface 132.

But in addition to particles present at surface 132, features of the structure of baseplate 112 can also be capable of reflecting or deflecting light 122 from illuminators 116 toward camera 140 as deflected light 122A. When this occurs, camera 140 detects that deflected light 122A and associates the light as being caused by particle contamination at surface 132. The result is a “false positive” reading that indicates the presence of particle contamination on the surface, when the signal was not generated by particle contamination.

A baseplate 112 can have different structures that can cause light 122 to be deflected as deflected light 122A in a direction to cause the deflected light 122A to be received by camera 140 and produce a false positive reading. A baseplate can be of a type useful for supporting, transferring, or otherwise supporting a reticle during an EUV photolithography step. Examples of useful baseplates can be of a type that is a component of a “reticle pod,” for example as described in United States Patent issued U.S. Pat. Nos. 9,745,119 and 9,919,863, and United States patent publication 2021/0057248, the entireties of which are incorporated herein by reference. These documents describe reticle pods that include a baseplate that supports a reticle during transport, and a cover that can be placed over the baseplate and reticle to protect the reticle during movement.

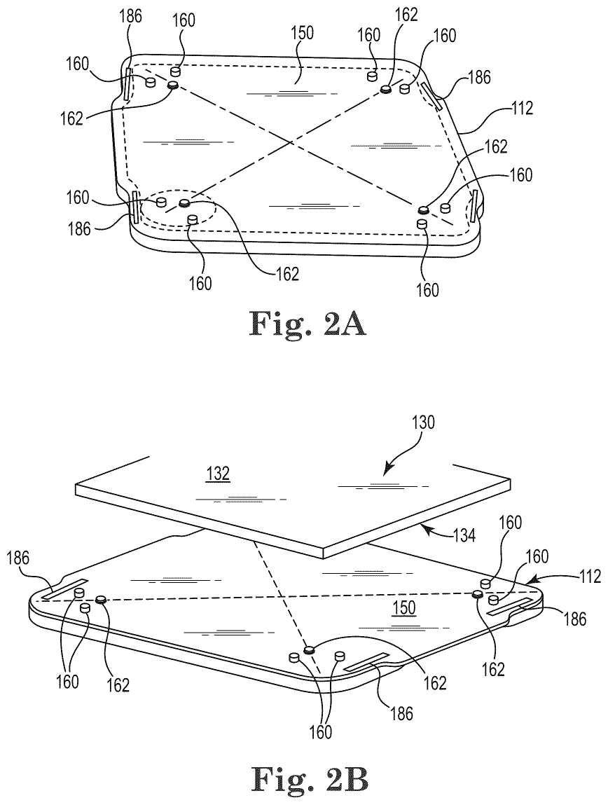

FIGS. 2A and 2B show an example of a baseplate 112 useful in exemplary reticle backside inspection system 100, and reticle 130. Baseplate 112 includes a location at a top surface 150 that approximates a size and shape of reticle. Patterned surface 134 of reticle 130 may be disposed in a “downward” direction toward upper surface 150 of baseplate 112. Upper surface 150 may be provided with a reflective metal finish, e.g., of reflective chrome, nickel, or the like.

Lateral containment pins 160 are mounted to baseplate 112 on upper surface 150. Multiple containment pins 160 are fixedly attached to baseplate 112 at locations near a perimeter of a space for locating reticle 130 above surface 150, and are effective to guide the placement of reticle 130 to a desired location above surface 150. In certain examples, containment pins 160 are shaped with a tapered, sloping surface to facilitate placement of reticle 130 between containment pins 160, are arranged in a regular pattern on surface 150, and are dimensioned and located to cause reticle 130 to become located at a desired location above surface 150 between the containment pins. Containment pins 160 may be constructed of metal, for example steel or aluminum, or may be of other rigid materials, including polymers.

In addition to containment pins 160, example baseplate 112 also includes a plurality of openings through the baseplate, and reticle supports 162 located within those openings. Each reticle support 162 is located within an opening or “aperture” that extends vertically through baseplate 112, and each reticle support 162 includes an upper surface that is located a small height above upper surface 150 of baseplate 112. The upper surface of reticle supports 162 are each individually positioned to be a slight distance above surface 150, to allow the upper surfaces of the reticle supports to contact a bottom (patterned) surface 134 of reticle 130 and to position the bottom surface 134 a slight distance above surface 150. The upper surface of each reticle support 162 is located a distance above upper surface 150, to separate lower surface 134 from upper surface 150 and to create a gap extending horizontally between the surfaces. The gap may be of any useful size for example in a range of from 0.001 to 0.010 inches.

As illustrated at FIGS. 2A and 2B, baseplate 112 includes multiple reticle supports 162 near pairs of containment pins 160 at corners of baseplate 112 on diagonals of surface 150, to contact surfaces of a reticle that are located near each of four corners of the reticle. Alternately, one or more reticle supports 162 may be positioned as desired at any other useful location of surface 150 as may be effective to provide support for reticle 130 above surface 150, desirably at locations that avoid contact with patterned or otherwise sensitive areas of patterned surface 134.

Relative to the present description, reticle 130 includes a functional (reflective) patterned surface over most of the area of patterned surface 134, but may not be patterned at areas that are adjacent to the perimeter edge of the reticle. The outer edge (“perimeter edge”) of the reticle may be un-patterned and transparent, thereby allowing light 122 to pass through the reticle at the location of the perimeter edge of the reticle. Light 122 that passes through reticle 130 at a perimeter edge may reach upper surface 150 of baseplate 112. If the location at which the light impinges on upper surface 150 is reflective and includes structure other than a horizontally-flat surface, e.g., if upper surface 150 includes a rounded or cornered edge or another non-horizontal structure (referred to as an “edge structure”), light 122 that passes through reticle 130 at the transparent perimeter edge may impinge on the edge structure and may be reflected or deflected toward camera 140 as deflected light 122A. That deflected light 122A may be received by camera 140 and cause system 100 to falsely associate deflected light 122A as being caused by particle contamination present at surface 132, i.e., produce a false-positive reading.

As described herein, the Applicant has identified structures (e.g., “low-reflecting surfaces” on an edge structure) and methods that reduce the occurrence of light 122 being deflecting or reflecting as light 122A from an edge structure of a baseplate, e.g., from an edge structure associated with upper surface 150, particularly at edge structures at a perimeter edge of a baseplate 112, and being re-directed toward camera 140 to produce a false positive reading.

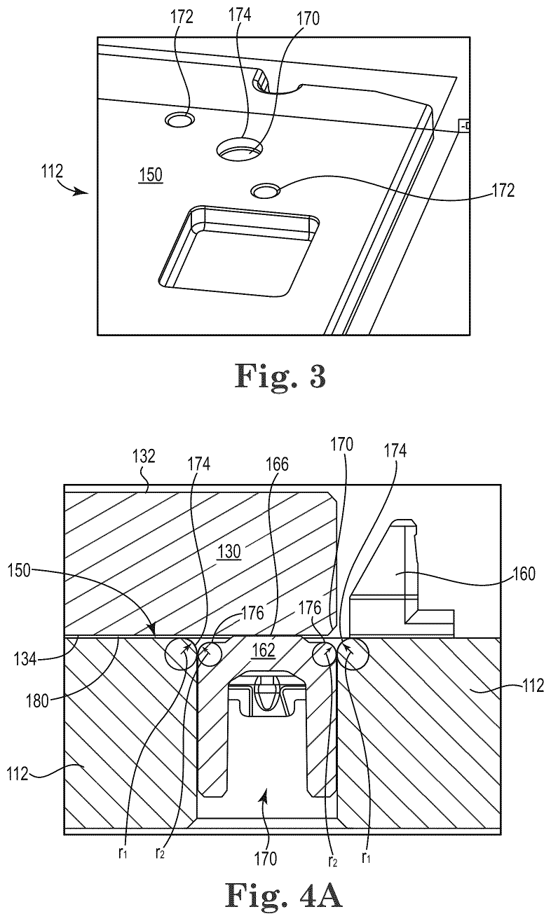

FIG. 3 is an upper perspective view of an example baseplate 112 with added detail.

Baseplate 112 includes horizontal upper surface 150 with openings or “apertures” 170 and 172. Aperture 170 is adapted to contain a reticle support 162 (not shown) and apertures 172 are each adapted to contain a containment pin 160 (not shown). Each aperture defines a circular edge (“edge structure”) between a vertical sidewall of the aperture and horizontal upper surface 150.

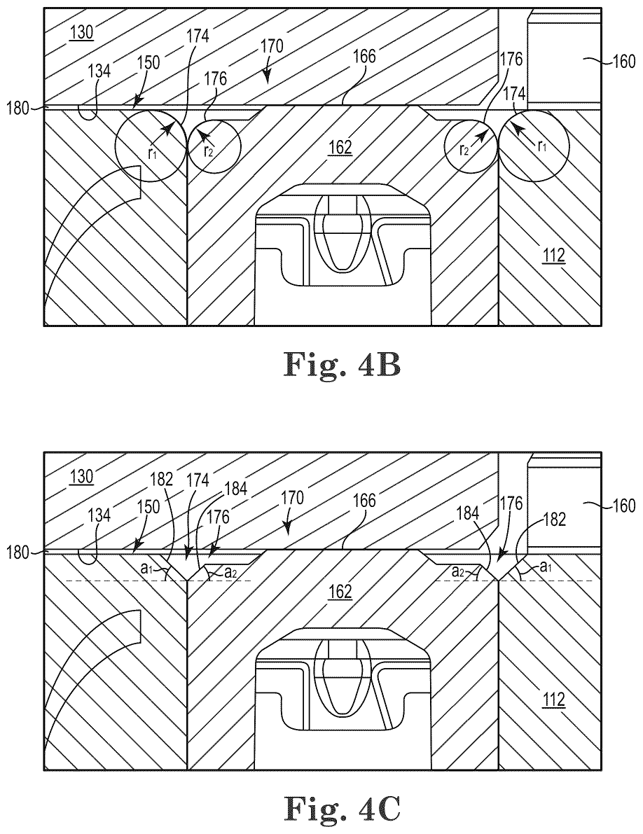

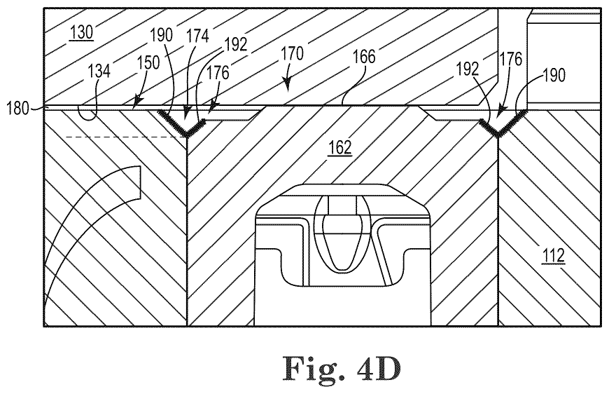

FIG. 4A, in cross section, shows baseplate 112, aperture 170 extending vertically through baseplate 112, reticle support 162 contained within aperture 170, containment pin 160, and reticle 130. Reticle 130 is supported by an upper surface of reticle support 162, which suspends reticle 130 a slight distance above surface 150, with patterned surface 134 of reticle 130 being separated from surface 150 by gap 180. Reticle support 162 contacts patterned surface 134 at a perimeter edge of the reticle, e.g., at a location that is not patterned but is transparent to light that is produced by illuminators of a reticle backside inspection system.

Aperture 170 includes circular edge structure 174 at a perimeter of aperture 170. In cross section (as shown at FIG. 4A) edge structure 174 has a rounded surface formed between horizontal surface 150 and the vertical sidewalls of aperture 170. Edge structure 174 has a radius of curvature designated by the circle having radius r1.

Also, at FIG. 4A, reticle support 162 includes circular edge structure 176 at the perimeter of reticle support 162 and adjacent to the horizontal upper surface of reticle support 162. In cross section (as shown at FIG. 4A) edge structure 176 has a rounded surface formed between the horizontal upper surface of reticle support 162 and vertically-extending outer cylindrical sidewalls of reticle support 162. The edge structure 176 has a radius of curvature that is designated by the circle having radius curvature r2.

A reticle support may be of any design, and can be designed to provide a support structure for a reticle that supports the reticle as described, slightly above an upper surface 150 of a baseplate, while reducing the presence of edge structures on a reticle support that could reflect or deflect light from an illuminator of a reticle backside inspection system in a direction toward a camera of the reticle backside inspection system.

In the example of FIG. 4A, reticle support 162 is a polymeric structure having an approximately cylindrical upper body with a relatively flat (horizontal) upper surface 166, and edge structure 176 extending around a perimeter of upper reticle surface 166. Aperture 170 has an inner diameter that is slightly smaller than the outer diameter of polymeric reticle support 162. Reticle support 162 is mounted within aperture 170 at a position to cause upper reticle surface 166 of reticle support 162 to protrude slightly above surface 150 to establish the height of the gap 180. Reticle support 162 may be held in place by a fastener (e.g., a set screw) that allows the height of the reticle support upper surface to extend above surface 150 and also allows for minute adjustments of the height of the upper surface above surface 150.

According to the present description, an EUV baseplate and baseplate structures such as a reticle support can be designed to prevent or to reduce an amount of light used in a reticle backside inspection system that is reflected from the baseplate and re-directed to a camera of the inspection system. The baseplate can include features that reduce the amount of light that is deflected or reflected from an edge surface of the baseplate in a direction that would cause the deflected light to reach a camera of the system and register a false positive reading; these features include “low-reflecting surfaces” applied to or formed on an edge structure. Additionally, or alternately, a baseplate can include features that, while the reticle is supported by a baseplate, reduce the amount of light that can pass through a transparent portion of the reticle, e.g., at a perimeter edge of the reticle, and reach the baseplate and potentially be re-directed toward the camera.

Example baseplates include edge structures that are non-horizontal. With a reticle supported by the baseplate, and at non-patterned areas of the reticle such as at a reticle perimeter edge, light that is directed onto the reticle backside to inspect for particles can pass through the reticle to reach the baseplate. Light that reaches the baseplate can be directed off of an edge structure of the baseplate and may be re-directed to a camera of the system. Example baseplates as described can be designed to reduce the amount of light that is deflected in this manner from edge structures of the baseplate toward the camera.

To reduce the amount of light that is deflected from an edge structure, example baseplates can include an edge structure that has a low-reflecting surface that may include, e.g.: an edge structure shape that reduces the amount of light that is reflected toward the camera; a low-reflecting surface on the edge structure formed by treating the edge structure surface to be less reflective or more absorbent of light used in the backside inspection system. Additionally, or alternately, the baseplate or system may include a structure (e.g., “screen” or a “mask”) that is located within the system, e.g., at an edge of the baseplate, to selectively block light of the inspection system from reaching the edge structure of the baseplate.

In various example baseplates, a low-reflecting edge structure can have a shape that allows a reduced, low, or minimum amount of light from an illuminator of a reticle backside inspection system to be reflected by the edge structure toward the camera. An edge structure may include a non-horizontal surface (e.g., a corner or edge) of an aperture or of a reticle support (e.g., 174, 176). To reduce the amount of light deflected from the edge structure, i.e., for the edge structure to function as a low-reflecting edge structure, the area of the non-horizontal surface of the edge structure is reduced or minimized, or can be angled to prevent light from being re-directed by the non-horizontal surface toward a camera of a reticle backside inspection system. For example, a corner may be formed to have a low radius of curvature. Alternately, the edge structure may be formed as a beveled (or “chamfered”) surface that is oriented at an angle that does not cause light to reflect from an illuminator toward a camera, e.g., that causes light that reaches the beveled surface to be directed at a shallow angle away from the camera. f

As shown at FIG. 4B, edge structure 174 of aperture 170 can be prepared to have a radius of curvature r1 that is less than 0.5 millimeters (500 microns), e.g., less than 0.4, 0.3, 0.2, or 0.1 millimeters (100 microns). The low radius of curvature edge structure will present a smaller curved surface area upon which light (122) may be reflected and re-directed as deflected light (122A) toward a camera of a reticle backside inspection system. The aperture 170 in baseplate 112 and the edge structure 174 can be produced in a metal baseplate by conventional machining techniques.

Similarly, as also shown at FIG. 4B, edge structure 176 of reticle support 162 can be prepared to have a radius of curvature r2 that is less than 0.5 millimeters (500 microns), e.g., less than 0.4, 0.3, 0.2, or 0.1 millimeters (100 microns). The low radius of curvature edge structure of the reticle support will present a smaller surface area upon which light (122) may be reflected and re-directed as deflected light (122A) toward a camera of a reticle backside inspection system. The reticle support 162 and edge structure 176 can be produced in a polymeric reticle support by standard polymeric molding or forming techniques.

According to an alternate embodiment, as shown at FIG. 4C, an edge structure 174 of aperture 170 can be prepared to have a beveled shape that is angled relative to a direction of light received from illuminators 116 of a reticle backside inspection system 100, to cause any reflected light to not be directed toward camera 140. An edge structure 174 may be defined as the transition from the vertical sidewalls of the aperture 170 to the beveled surface 182. Beveled surface 182 of edge structure 174 is angled to cause light (122) of a backside inspection system to be reflected at a shallow angle that not re-directed as deflected light (122A) toward a camera of a reticle backside inspection system. The angles a1 can be any angle that light that is deflected by beveled surface 182 in a direction that does not cause the light to be received by camera 140. Examples of useful values of angle a1 between beveled surface 182 and surface 150 can be less than 15 degrees or greater than 75 degrees, as indicated. The aperture 170 in baseplate 112 and the edge structure 174 with beveled surface 182 can be produced in a metal baseplate by conventional machining techniques.

According to a similar embodiment also shown at FIG. 4C, edge structure 176 of reticle support 162 can be prepared to have a beveled shape that is angled relative to a direction of light received from illuminators 116 of a reticle backside inspection system 100, to cause any reflected light to not be directed toward camera 140. Beveled surface 184 of edge structure 176 is angled to cause light (122) of a backside inspection system to be reflected at a shallow angle that is not re-directed as deflected light (122A) toward a camera of a reticle backside inspection system. The angles a2 can be any angle that directs deflected light in a direction that does not cause the light to be received by camera 140. Examples of useful values of angle a2 between beveled surface 184 and surface 150 can be less than 15 degrees or greater than 75 degrees, as indicated. The reticle support 162 and edge structure 176 can be produced in a polymeric reticle support by standard polymeric molding and forming techniques.

According to alternate baseplates shown at FIG. 4D, an edge structure 174 of aperture 170 can be prepared to include a low-reflecting surface 190 that, based on composition or texture (roughness versus smoothness) but not necessarily on shape (e.g., a low radius of curvature corner or a beveled shape), has a reduced ability to reflect light 122 of illuminators 116 of a backside inspection system (i.e., has a low spectral reflectance), or that adsorbs light 122 of illuminators 116 of a backside inspection system. The shape of the edge structure may be rounded at any radius of curvature, beveled, or otherwise shaped, while the composition or texture of the edge structure surface causes the edge structure surface to function as a low-reflective surface.

A low-reflecting surface 190 may be any surface that has a composition (e.g., by an applied coating or a treatment applied to the surface) or a texture, that exhibits a lower reflectivity compared to other surfaces of aperture 170 or baseplate 112, e.g., a lower reflectivity compared to the reflectivity of surface 150 of baseplate 112 as measured by spectral reflectance of light having a wavelength emitted by illuminators of a reticle backside inspection system. A low-reflecting surface 190 of an edge structure 174 of a metal baseplate may have a reflectivity of light emitted by an illuminator of a reticle backside inspection system that is at least 10, 20, 30, 40, 50 percent lower, compared to a reflectivity of surface 150 of baseplate 112, measured as spectral reflectance of light emitted by an illuminator 116. The wavelength of the light may be a single wavelength or a range of wavelengths of light produced by an illuminator of a reticle backside system and directed toward a reticle surface to detect particle contamination at the surface.

A typical surface 150 of a baseplate 112 is a metal (e.g., chrome, nickel, or the like) surface that is highly reflective of light over a range of visible wavelengths. Typically, an edge surface 174 and aperture 170 include the same reflective metal surface, e.g., applied as a coating over a metal (e.g., aluminum) baseplate structure. The metal surface of the edge structure can reflect light received from an illuminator of a reticle baseplate inspection system and can re-direct that light toward a camera of the system, causing a false positive reading. A metal (e.g., chrome) surface of a baseplate can have a spectral reflectance that exceeds 60 percent of wavelengths emitted by illuminators of a reticle backside inspection system. For example, a metal surface or edge structure (150, 174) made of chrome can have a spectral reflectance of greater than 60 percent, e.g., of approximately 63 percent, of light having a wavelength emitted by the illuminator.

Examples of low-reflecting surface 190 can have a spectral reflectance of the same wavelength light, a wavelength of light that is emitted by the illuminator, that is below 63 percent, below 60 percent, or below 55, 50, 45, 40, 30, or 20 percent. Examples low-reflecting surfaces may be made of an oxide of the metal surface of the edge structure, e.g., chrome oxide or nickel oxide.

According to example baseplates, a highly reflective metal surface of an edge structure 174 of an aperture 170 may be modified to reduce the reflectivity (measured as spectral reflectance) of the surface and produce a low-reflecting surface 190. For example, a highly reflective metal coating at a surface of an edge structure (e.g., 174) may be treated by chemical etching, laser texturing, laser ablation, or mechanical abrasion, or a combination of these, to reduce the reflectivity of the surface and produce a low-reflecting surface 190.

The treatment may affect the chemical makeup of the metal, the texture of the metal surface, or both. The low-reflecting surface 190 that results from the treatment may have a surface that is at least 10, 20, 30, 40, or 50 percent lower in reflectivity of light emitted by an illuminator of a reticle backside inspection system (as measured by spectral reflectance), compared to a reflectivity of surface 150 of baseplate 112, or compared to the reflectivity of the untreated surface of the edge structure 174, or both. For example, a low-reflecting surface may have a spectral reflectance of light of a wavelength emitted by an illuminator that is below 63 percent, below 60 percent, or below 55, 50, 45, 40, 30, or 20 percent.

Alternately or additionally, a reflective metal coating at a surface of an edge structure 174 of a metal baseplate may be coated with a material different from the material of surface 150, and that that has a lower reflectivity of light 122 emitted by an illuminator 116, or that absorbs light 122 emitted by an illuminator 116, to produce a low-reflecting surface 190. The low-reflecting surface 190 produced by the coating (optionally in combination with chemical treatment, laser treatment, mechanical abrasion, etc.) may be at least 10, 20, 30, 40, or 50 percent lower in reflectivity of light emitted by an illuminator of a reticle backside inspection system (as measured by spectral reflectance), compared to a reflectivity of surface 150 of baseplate 112, and compared to the reflectivity of the untreated (uncoated) surface of edge structure 174.

A coating that can be useful to produce a low-reflecting surface 190 may be any coating that can be applied to a surface of an edge structure and that has a reflectivity as measured by spectral reflectance that is lower than a reflectivity of surface 150 of baseplate 112, or that is lower than the reflectivity of the untreated surface of the edge structure 174, or both; e.g., a spectral reflectance of light of a wavelength emitted by an illuminator that is below 63 percent, below 60 percent, or below 55, 50, 45, 40, 30, or 20 percent.

Also shown at FIG. 4D, an edge structure 176 of reticle support 162 can be prepared to have a low-reflecting surface 192 that has a reduced ability to reflect light 122 of illuminators 116 of a backside inspection system, or that adsorbs light 122 of illuminators 116 of a backside inspection system, to prevent light 122 from being reflected light from the edge structure surface toward camera 140.

The low-reflecting surface 192 may be any surface that has a chemical makeup or a texture that results in a desirably low reflectivity, optionally but not necessarily including a lower reflectivity compared to other surfaces of reticle support 162, as measured by spectral reflectance of light of a wavelength emitted by illuminators of a reticle backside inspection system.

In example baseplates of the present description, an edge structure 176 of reticle support 162 may include a texture that exhibits a desirably low reflectivity of the edge structure surface and produce a low-reflecting surface 192. For example, a polymeric surface of an edge structure (e.g., 176) may be treated to roughen the surface by chemical etching, laser texturing, laser ablation, or mechanical abrasion, or a combination of these, to reduce the reflectivity of the surface and produce a low-reflecting surface 192. The surface may also be produced to have a non-smooth, e.g., roughened low-reflecting surface during molding of forming of reticle support 162. A low-reflecting surface 192 that is formed by treating the surface to form a low-reflecting surface (a textured, roughened surface) polymeric surface by chemical etching, laser texturing, laser ablation, or mechanical abrasion, may have a surface that is at least 10, 20, 30, 40, or 50 percent lower in reflectivity of light emitted by an illuminator of a reticle backside inspection system (as measured by spectral reflectance), compared to a reflectivity of the polymeric surface prior to the being treated.—

Alternately or additionally, a polymeric surface of an edge structure 176 may be coated with a material that is different from the polymeric material of edge structure 176, and that has a desirably low reflectivity of light 122 emitted by an illuminator 116, or that absorbs light 122 emitted by an illuminator 116, to produce a low-reflecting surface 192. The low-reflecting surface 192 of the coating (optionally in combination with chemical treatment, laser treatment, mechanical abrasion, etc.) may be at least 10, 20, 30, 40, or 50 percent lower in reflectivity of light emitted by an illuminator of a reticle backside inspection system (as measured by spectral reflectance), compared to a reflectivity of the un-coated polymeric surface of the edge structure 176, or compared to a reflectivity of surface 150 of baseplate 112.

A coating that can be useful to produce a low-reflecting surface 192 may be any coating that can be applied to a polymeric surface of edge structure 176, and that has a reflectivity as measured by spectral reflectance that is at least lower than a reflectivity the uncoated surface of edge structure 176.

In other example systems, a baseplate used in a reticle backside inspection system can include a structure such as a light screen (“screen” or “mask”) that reduces the amount of light or prevents light from being directed toward a reticle at a transparent area of the reticle, such as at a reticle perimeter edge, to thereby prevent the light from passing through the transparent area of the reticle, reaching a baseplate that supports the reticle, and reaching an edge structure of the baseplate that may potentially re-direct the light toward a camera of the inspection system.

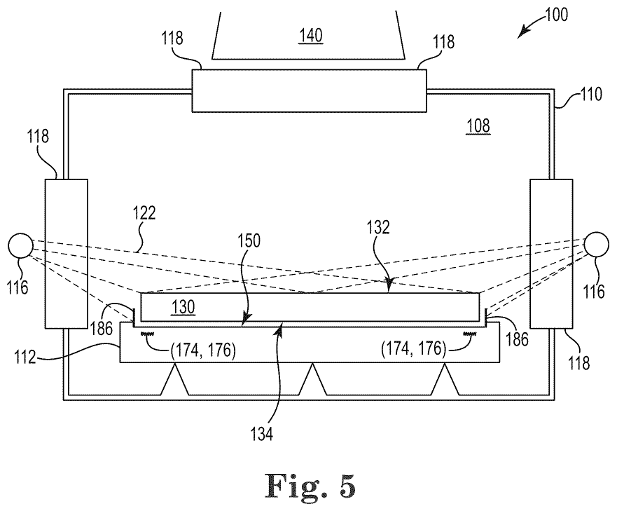

FIG. 5 shows example reticle backside inspection system 100, which includes features of system 100 of FIG. 1, includes a vacuum housing 110, vacuum chamber 108, reticle baseplate 112, kinematic 114, and reticle 130 having a lower (patterned) surface 134 supported by baseplate 112 and an upper surface (the reticle “backside”) 132 is facing upward toward vacuum chamber 108 and camera 140. Illuminators 116 produce light 122 at a wavelength that passes through windows 118. Light 122 is directed toward surface 132 to inspect for particles that may be present at surface 132.

Baseplate 112 is illustrated as including edge structures that are capable of deflecting light from illuminators 116 in a direction toward camera 140, if the light passes through reticle 130 and reaches the edge structures, which may be structures 174, 176, or both, of an aperture 170 and a reticle support 162 as described.

System 100 of FIG. 5 additionally includes light screens 186 that are supported by baseplate 112. A light screen (or “screen”) 186 may be any structure that can be placed at an edge of baseplate 112 at a location between an illuminator 116 and reticle 130, particularly at a location between an illuminator 116 and an edge structure of baseplate 112 as exemplified by structures 174, 176. In this embodiment, light screen 186 is positioned vertically. Light screen 186 is non-transmissive of light 122 and prevents light 122 from reaching reticle 130, or prevents light 122 from reaching an edge structure 174, 176, that could re-direct light 122 toward camera 140.

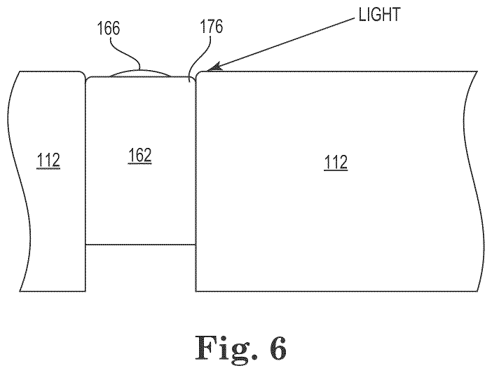

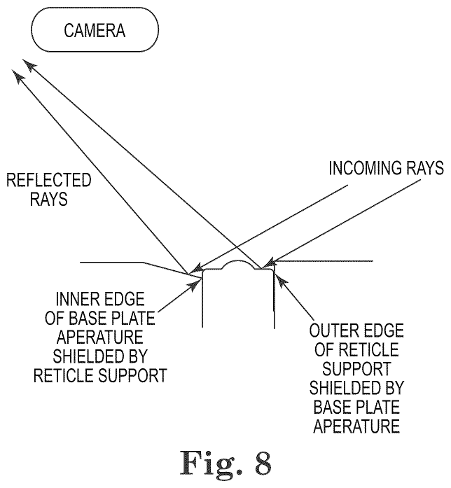

Screens 186 may be placed at any useful location on a baseplate, to prevent light from reaching a reticle 130 or an edge structure (e.g., 174, 176) of a base. FIGS. 2A and 2B show useful locations of screens 186, positioned near a perimeter edge of baseplate 112 and near edge structures of reticle support 162, and an associated aperture (not shown). Additionally, FIG. 6 depicts another embodiment where the baseplate 112 functions as a light screen for the reticle support body 162 and prevents light from striking the reticle support edge 176. In this embodiment the reticle support edge is positioned below the upper surface of baseplate 112. Edge structures of a reticle 130 be a transition from the containment pins 160 to the beveled edge structure. Additionally, FIG. 8 depicts another embodiment where the reticle support edge structure blocks light from the aperture edge structure.

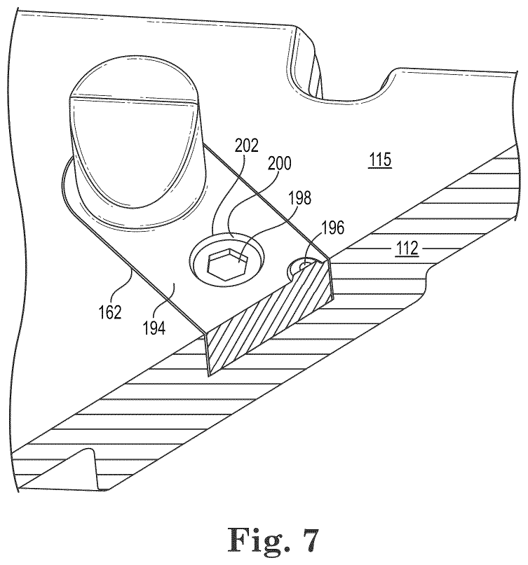

Reticle supports positioned on the baseplate may also reflect light due to either the surface of the reticle support or by fasteners used to retain the reticle support onto the baseplate. The incidental reflection of light could also become problematic and a create false positive reading. In another embodiment as depicted in FIG. 7, a baseplate 112 for supporting a reticle (not shown) includes a horizontal baseplate surface 115, and a reticle support 162 located on the horizontal baseplate surface 115. The reticle support 162 includes a base 194 and at least one reticle contact feature 196 extending from the base 194. At least one reticle contact feature on the distal end of the support structure 162. The base 194 may include one or more fasteners 198 to retain the base on the horizontal baseplate surface. The one or more fasteners 198 are recessed into a counter bore 200 obscuring the edges from shallow angle light. In another embodiment, the fastener 198 or the edge structure 202 includes a low-reflecting surface created from; (i) a bevel, (ii) a radius of curvature of less than 0.3 millimeters, (iii) a surface having a spectral reflectance that is at least 10 percent lower than a spectral reflectance of the upper baseplate surface, or (iv) a combination thereof.

1. A baseplate for supporting a reticle, the baseplate comprising:
a horizontal baseplate surface,
an aperture located vertically through the plate, the aperture comprising an aperture edge structure formed between a vertical aperture sidewall and the baseplate surface,
a reticle support located within the aperture, the reticle support comprising:
a reticle support body that engages the aperture sidewall,
an upper reticle support surface that is located above the horizontal plate surface and is adapted to support a reticle above the baseplate surface, and
a reticle support edge structure formed between the reticle support body and the reticle support surface,
wherein:
the aperture edge structure comprises a low-reflecting surface comprising: a bevel, a radius of curvature of less than 0.3 millimeters, a surface having a spectral reflectance that is at least 10 percent lower than a spectral reflectance of the upper baseplate surface, or a combination of these;
the reticle support edge structure comprises a low-reflecting surface comprising: a bevel, a radius of curvature of less than 0.3 millimeters, a surface having a spectral reflectance that is at least 10 percent lower than a spectral reflectance of the upper baseplate surface, or a combination of these; or
at least one light screen positioned on the baseplate surface wherein the at least one light screen is non-transmissive of light and prevents light from reaching the aperture edge structure or the reticle support edge structure.

2. The baseplate of claim 1, wherein the aperture edge structure comprises a low-reflective coating having a spectral reflectance that is at least 50 percent lower than the spectral reflectance of the upper baseplate surface.

3. The baseplate of claim 1, wherein the aperture edge structure comprises a textured surface formed by a treatment selected from: chemical etching, laser texturing, laser ablation, or mechanical abrasion.

4. The baseplate of claim 1, wherein the reticle support edge structure comprises a low-reflective coating having a spectral reflectance that is at least 50 percent lower than the spectral reflectance of the upper baseplate surface.

5. The baseplate of claim 1, wherein the reticle support edge structure comprises a textured surface formed by a treatment selected from: chemical etching, laser texturing, laser ablation, or mechanical abrasion.

6. The baseplate of claim 1, further comprising a reticle supported at the baseplate upper surface.

7. The baseplate of claim 1, wherein the bevel of the aperture edge structure is angled outside the range of 15 degrees and 75 degrees.

8. The baseplate of claim 1, wherein the bevel of the reticle edge structure is angled outside the range of 15 degrees and 75 degrees.

9. The baseplate according to claim 1, wherein a lower edge of the bevel of the aperture edge structure is in a lower position relative to the reticle support edge structure such that the reticle support edge structure shields a lower edge of the bevel of the aperture edge structure from light.

10. The baseplate according to claim 1, wherein a lower edge of the bevel of the reticle support edge structure is in a lower position relative to the baseplate such that the baseplate shields a lower edge of the bevel of the reticle support edge structure from light.

11. A reticle backside inspection device comprising:
a vacuum chamber comprising an interior,
a baseplate according to claim 1 at the interior,
an illuminator capable of directing light toward the baseplate, and
a camera adapted to detect light re-directed by particles on a backside surface of a reticle supported on the baseplate upper surface.

12. A method of using a reticle backside inspection device of claim 11, the method comprising:
supporting a reticle at the baseplate upper surface;
directing light from the illuminator toward the reticle;
using the camera to detect light reflected by particles at a surface of the reticle.

13. The method of claim 12, comprising using the light detected by the camera to determine an amount of particles at the reticle surface.

14. A reticle backside inspection device comprising:
a vacuum chamber comprising an interior,
a baseplate having an upper surface and an edge structure,
an illuminator capable of directing light onto the baseplate upper surface, and
a camera,
wherein the baseplate comprises:
a horizontal upper baseplate surface,
an aperture located vertically through the plate, the aperture comprising an aperture edge structure formed between a vertical aperture sidewall and the upper baseplate surface,
a reticle support located within the aperture, the reticle support comprising:
a reticle support body that engages the aperture sidewall,
an upper reticle support surface that is located above the horizontal plate upper surface and is adapted to support a reticle above the upper baseplate surface, and
a reticle support edge structure formed between the reticle support body and the upper reticle support surface,
and wherein:
the aperture edge structure comprises a low-reflecting surface comprising: a bevel, a radius of curvature of less than 0.3 millimeters, a surface having a spectral reflectance of less than 60 percent at a wavelength of light emitted by the illuminator, or a combination of these;
the reticle support edge structure comprises a low-reflecting surface comprising: a bevel, a radius of curvature of less than 0.3 millimeters, a surface having a spectral reflectance of less than 60 percent at a wavelength of light emitted by the illuminator, or a combination of these; or
at least one light screen positioned on the baseplate surface wherein the at least one light screen is non-transmissive of light and prevents light from reaching the aperture edge structure or the reticle support edge structure.

15. The inspection device of claim 14, wherein the aperture edge structure comprises a low-reflective coating having a spectral reflectance of less than 50 percent at a wavelength of light emitted by the illuminator.

16. The inspection device of claim 14, wherein the aperture edge structure comprises a textured surface formed by a treatment selected from: chemical etching, laser texturing, laser ablation, or mechanical abrasion.

17. The inspection device of claim 14, wherein the reticle support edge structure comprises a low-reflective coating having a spectral reflectance of less than 50 percent at a wavelength of light emitted by the illuminator.

18. The inspection device of claim 14 wherein the reticle support edge structure comprises a textured surface formed by a treatment selected from: chemical etching, laser texturing, laser ablation, or mechanical abrasion.

19. A baseplate for supporting a reticle, the baseplate comprising:
(a) a horizontal baseplate surface,
(b) a reticle support located on the horizontal baseplate surface, the reticle support having:
(i) a base, and
(ii) a support structure extending from the base, the support structure having an edge structure and at least one reticle contact feature on a distal end of the reticle support structure, wherein the base includes (1) fasteners to retain the base on the horizontal baseplate surface, and wherein the fasteners are recessed into a counter bore obscuring the edges from shallow angle light, or (2) the fastener or the edge structure comprises a low-reflecting surface comprising: a bevel, a radius of curvature of less than 0.3 millimeters, a surface having a spectral reflectance that is at least 10 percent lower than a spectral reflectance of the upper baseplate surface, or a combination thereof.

20. The baseplate of claim 19, wherein the edge structure comprises a textured surface formed by a treatment selected from: chemical etching, laser texturing, laser ablation, or mechanical abrasion.
